(19) United States
(12) Patent Application Publication
(10) Pub. No.: US 2024/0379326 A1
(43) Pub. Date: Nov. 14, 2024

(54) METHOD FOR OPERATING AN ELECTRON BEAM SYSTEM

(71) Applicant: Carl Zeiss Microscopy GmbH, Jena (DE)

(72) Inventor: Bjoern Gamm, Koenigsbronn (DE)

(21) Appl. No.: 18/658,499

(22) Filed: May 8, 2024

(30) Foreign Application Priority Data
May 9, 2023 (DE) 10 2023 112 074.3

(51) Int. Cl. H01J 37/26; H01J 37/14; H01J 37/21

(52) U.S. Cl. CPC H01J 37/265; H01J 37/14; H01J 37/21; H01J 2237/2485

(57) ABSTRACT

A method for operating an electron beam system comprises setting a first potential supplied to an electron emitter to a first value, a second potential supplied to a beam tube to a second value and a third potential supplied to an object to a third value such that the third potential is greater than the first potential and the second potential is greater than the third potential. The method also comprises focusing a beam of the electron beam system on the object by modifying at least one current supplied to at least one focusing magnetic lens.

### CROSS-REFERENCE TO RELATED APPLICATION

This application claims benefit under 35 U.S.C. § 119 to German Application No. 10 2023 112 074.3, filed May 9, 2023. The entire disclosure of this application is incorporated by reference herein.

### FIELD

The present application relates to methods for operating electron beam systems.

### BACKGROUND

Electron beam systems comprise a beam source which generates an electron beam. The electron beam illuminates a spot on an object, the size of which is reduced as far reasonably as possible when focusing through an objective lens. The spot illuminated by the electron beam can be scanned over a region on the object by the electron beam system by virtue of the electron beam being deflected from its trajectory. Electron beam systems also comprise a detector which can be used to detect electrons that are emitted by the object having been generated when the electron beam is incident on the object. An electron-microscopic image is generated by assigning the deflection of the electron beam to the measurements from the detector. An achievable resolution of the electron-microscopic image is higher when the illuminated spot is smaller.

In certain electron beam systems, the electron beam passes through a beam tube over a majority of the path between the beam source and the object. The beam tube is supplied with an electric potential in order to accelerate the electrons in the beam when entering into the beam tube and, upon exit of these electrons from the beam tube, decelerate these between the beam tube and the object by way of the field of an electrostatic lens of the electron beam system. As a result, the electrons in the beam reach the object quicker and consequently experience less of the electrostatic repulsion, which can increase the spot of the beam on the object, due to other electrons in the beam. Accordingly, the potential supplied to the beam tube is chosen to be as high as reasonably possible during the conventional operation of these electron beam systems so that the spot is as small as possible and hence the achievable resolution of recorded electron-microscopic images is as high as possible.

However, a user might consider this conventional operation of the electron beam systems inadequate.

### SUMMARY

The present invention proposes a method for improved operation of electron beam systems with a beam tube.

According to embodiments of the invention, a method for operating an electron beam system comprises a setting of a first potential supplied to an electron beam source to a first value, a second potential supplied to a beam tube to a second value and a third potential supplied to an object to a third value such that the third potential is greater than the first potential and the second potential is greater than the third potential. This means that the potential supplied to the beam tube is greater than the potential supplied to the object. This is used for decelerating the electrons. Moreover, the potential supplied to the object is greater than the potential supplied to the electron beam source so that the electrons in the beam are in fact incident on the object.

If a potential is supplied to an electron beam system as described above, then an electrostatic field which already deflects electrons of an electron beam by the electrostatic interaction therewith and which acts on the electrons like a focusing lens is prevalent between the beam tube and the object. Accordingly, the electron beam system has a focusing effect on the electron beam even if no current is supplied to any magnetic lens, for example an objective lens, provided to this end. Once such a state has been achieved, for example while focusing the electron beam on the object arranged at a large distance from the electron beam system, the focusing can be continued if the potential supplied to the beam tube is reduced. If the potential supplied to the beam tube is reduced, then the current supplied to the objective lens can be increased for an unmodified focusing effect since the focusing effect of the electrostatic field is smaller. Consequently, focusing can be continued. In this case, the potential supplied to the beam tube can also correspond to a ground potential.

According to embodiments, the method also comprises focusing the beam on the object by modifying at least one current which is supplied to at least one magnetic lens such as an objective lens, for example, wherein the following are carried out if the at least one current meets a predetermined criterion during the focusing: setting the potential supplied to the beam tube to a fourth value which is less than the second value and increasing the at least one current and then continuing to focus the beam on the object by modifying the at least one current, or keeping the at least one current constant and then continuing to focus the beam on the object by modifying the second potential. This means that while the beam is focused on the object, the potential supplied to the beam tube is reduced and for example the current supplied to the objective lens is increased if a predetermined criterion is satisfied. Focusing can then be continued by modifying the objective lens current or modifying the potential supplied to the beam tube.

The method can be performed using an electron beam system which comprises an electron beam source for generating a beam of electrons, a beam tube which comprises a first end and a second end and is configured such that the beam of electrons enters the beam tube at the first end thereof and emerges from the beam tube at the second end thereof, at least one focusing magnetic lens through which the electron beam passes, and a supply system configured to supply the first potential to an electron emitter of the electron beam source, supply the second potential to the beam tube, supply the third potential to the object and supply the at least one current to the at least one magnetic lens.

For example, the at least one magnetic lens can be an objective lens of the electron beam system or else an objective lens and a condenser lens of the electron beam system.

Focusing is a lengthy process which generally comprises a plurality of steps.

Accordingly, it is possible to start with focusing the beam on the object and adopt further measures during the focusing, for example reducing the potential supplied to the beam tube. A check as to whether these measures are made by comparing the current supplied to the objective lens with a predetermined criterion can be performed during each focusing step, for example. Alternatively, the aforementioned check can also be implemented after every second step, every third step, etc.

According to some embodiments, the predetermined criterion is met if the current supplied to the objective lens drops below a predetermined value. In particular, the predetermined value can be virtually zero, whereby the criterion is met when the current supplied to the objective lens is virtually zero.

According to a further embodiment, the method comprises a setting of a first potential supplied to an electron beam source to a first value, a second potential supplied to a beam tube to a second value and a third potential supplied to an object to a third value such that the third potential is greater than the first potential and the second potential is greater than the third potential. The method also comprises a focusing of a beam on an object by modifying at least one current which is supplied to at least one magnetic lens, wherein the following are carried out if the at least one current meets a predetermined criterion during the focusing: setting the second potential to a fourth value which is greater than the second value and reducing the at least one current and then continuing to focus the beam on the object by modifying the at least one current, or keeping the at least one current constant and then continuing to focus the beam on the object by modifying the second potential. The method according to this embodiment is the reversed method to the method described above and for example comprises an increase in the potential supplied to the beam tube and a reduction in the current supplied to the objective lens while the beam is focused on the object if a predetermined criterion is met.

According to some embodiments, the predetermined criterion is met if a current of the at least one current exceeds a predetermined value.

According to some embodiments, electrons between the second end of the beam tube and the object are influenced by an electric field generated by a difference between the second potential and the third potential, and by a field generated by the magnetic lens. In particular, the beam tube and the objective lens of the electron beam system are arranged such that the electric field generated by the potential supplied to the beam tube and the potential supplied to the object spatially overlaps with the field generated by the magnetic lens.

According to some embodiments, the predetermined criterion depends on the second value of the potential supplied to the beam tube. To be exact, the predetermined criterion may depend on a focusing effect of the electron beam system which is generated by the current supplied to the objective lens and the potential supplied to the beam tube. If, like in the embodiments described above, the criterion is met when the current supplied to the objective lens drops below a predetermined value and the predetermined value is small, then the focusing effect of the electron beam system in the setting for which the criterion is met will depend virtually exclusively on the second value of the potential supplied to the beam tube.

According to some embodiments, focusing the beam on the object comprises finding a value for the current such that a spot illuminated by the beam on the object is as small as possible.

According to some embodiments, focusing the beam on the object comprises a detection of electrons generated by the beam of electrons, a determination of a change in a value of the current, supplied to the magnetic lens, on the basis of the detected electrons and a setting of the value for the current in accordance with the determined change. For example, focusing can be performed in the following way: an electron-microscopic image is recorded by the electron beam system, the electron-microscopic image is analysed and a value of the at least one current is modified on the basis of a result of the analysis. For example, a sharpness of the electron-microscopic image can be analysed in the process. For example, the sharpness of the electron-microscopic image can be determined by virtue of the electron-microscopic image being subject to a Fourier transform and the contributions of the frequencies being observed.

According to some embodiments, the method also comprises a recording of at least one electron-microscopic image at the set values of the potential supplied to the beam source, of the potential supplied to the beam tube and of the potential supplied to the object and of the current supplied to the magnetic lens.

According to some embodiments, focusing the beam on the object comprises finding a value for the current such that the recorded electron-microscopic image is as sharp as possible. As already mentioned above, a sharpness of the electron-microscopic image can be defined by virtue of the Fourier transform of the image having as many high-frequency contributions as possible.

As already described above, a potential supplied to the beam tube is conventionally set as high as possible in the electron beam system in order to increase the possible resolution. However, the situation may arise where a user of the electron beam system discovers that an image, once recorded, is unsuitable for their purposes, for example because certain structures are unrecognizable. Therefore, it may be advantageous to switch from an operating mode with a high resolution to an operating mode with a high detected signal from the detector. In this case, an operating mode with a high detected signal from the detector means that the number of electrons incident on the detector is as large as possible. This is possible since the focusing effect of the electrostatic field and magnetic objective lens field between the beam tube and the object also acts on electrons such as electrons emitted by the object which pass through the beam tube in the opposite direction to the electron beam. Therefore, trajectories of such electrons are influenced directly by the potential supplied to the beam tube. If the potential supplied to the beam tube is modified for this purpose then it is desirable to adjust the current supplied to the magnetic lens so that the entire focusing effect acting on the electron beam remains the same. Accordingly, the composition of magnetic and electrostatic influence on the electrons emitted by the object is always modified.

Accordingly, the method according to this further embodiment comprises a setting of a first potential supplied to an electron emitter of the electron beam source to a first value, a second potential supplied to a beam tube to a second value and a third potential supplied to an object to a third value such that the third potential is greater than the first potential and the second potential is greater than the third potential. This means that the potential supplied to the beam tube is greater than the potential supplied to the object. This is used for decelerating the electrons. Moreover, the potential supplied to the object is greater than the potential supplied to the electron beam source so that the electrons in the beam are in fact incident on the object.

The method also comprises a focusing of the beam on the object by modifying the at least one current to a fourth value and recording a first electron-microscopic image at the first value of the first potential, the second value of the second potential, the third value of the third potential and the fourth value of the current, a setting of the second potential to a fifth value which is less than the second value, a setting of the current to a sixth value which is less than the fourth value, and a recording of a second electron-microscopic image at the first value of the first potential, the fifth value of the second potential, the third value of the third potential and the sixth value of the current. This means that a first image is recorded first at the originally set values and a second image is then recorded at new values, at which the potential supplied to the beam tube and the current supplied to the magnetic lens are reduced.

According to some embodiments, the method also comprises a determination of the fifth value and the sixth value on the basis of the first value, the second value, the third value and the fourth value such that the beam is substantially focused on the object at the first value of the potential supplied to the electron beam source, the fifth value of the potential supplied to the beam tube, the third value of the potential supplied to the object and the sixth value of the current. For example, this comprises that the beam of electrons makes a small spot on the object, as already described above.

According to some embodiments, the method also comprises a use of a predetermined data record when determining the fifth value and the sixth value, wherein the data record comprises a multiplicity of tuples of values of the potential supplied to the electron beam source, the potential supplied to the beam tube, the potential supplied to the object, the current and a distance of the electron beam system, at which the focus of the beam arises. For example, the predetermined data record can be generated by a simulation of trajectories of electrons in the beam. Alternatively, the predetermined data record can also be created by operations of the electron beam system, by virtue of used settings of the electron beam system being recorded. The data record can also be stored in a local memory of the electron beam system or, for example, in a cloud to which the electron beam system has access.

According to some embodiments, the electron beam system further comprises a detector arranged next to the beam of electrons within the beam tube, and the determination is implemented in such a way that an intensity of electrons incident on the detector or a ratio of a current of the beam of electrons focused on the object to the intensity of electrons incident on the detector is greater than during the recording of the first electron-microscopic image. For example, the detector may comprise a scintillator crystal and a detector area, with which electrons entering into the scintillator crystal can be detected. The scintillator crystal can be held by a mount next to the beam of electrons within the beam tube. Alternatively, the detector may have a structure which guides electrons entering the structure to a scintillator crystal and a detector area which are then able to detect the electrons. The detector may also be a semiconductor detector or have a different construction.

According to some embodiments, the second value is chosen such that a resolution of the first image is maximal.

According to some embodiments, the determination is implemented in such a way that a convergence angle of the beam of electrons focused on the object is smaller than during the recording of the first electron-microscopic image.

According to some embodiments, the electron beam system further comprises an ion beam column configured to direct an ion beam at a region of the object which can also be scanned by the electron beam. The method further comprises an operation of the ion beam column while the second electron-microscopic image is recorded. For example, ions of the ion beam can be gallium ions.

According to some embodiments, the operation of the ion beam column comprises a removal of material from the object using the ion beam or a severing of material from the object by the ion beam.

According to some embodiments, an electron beam system comprises an electron beam source for generating a beam of electrons, a beam tube which comprises a first end and a second end and is configured such that the beam of electrons enters the beam tube at the first end thereof and emerges from the beam tube at the second end thereof, at least one focusing magnetic lens through which the electron beam passes, a supply system configured to supply a first potential to an electron emitter of the electron beam source, supply a second potential to the beam tube, supply a third potential to an object and supply at least one current to the at least one magnetic lens, and a controller configured to perform the method according to any of Claims 1 to 17. Further, the electron beam system can comprise an ion beam column configured to direct an ion beam at the object.

It should be observed that the beam tube of the above-described electron beam systems is not restricted to a single beam tube. For example, the beam tube may comprise a plurality of beam tube portions which each have a plurality of ends. In such a case, it is possible for example for the first end to be an end of a first beam tube portion and the second end to be an end of a second beam tube portion. Additionally, it should be observed that the second end of the beam tube in advantageous embodiments is arranged in the proximity of the objective lens, in particular at a distance from the objective lens which is less than 0.1-times the distance between the electron beam source and the objective lens. Moreover, the first end of the beam tube need not necessarily be arranged in the proximity of a condenser lens of the electron beam system. All that is important is that the beam tube has an extent along the beam path and the beam tube can accordingly develop the above-described effect with regards to the acceleration of the electrons in the beam.

Additionally, it should be observed that different potentials can be supplied to the beam tube portions in the above-described case where the beam tube comprises a plurality of mutually separated beam tube portions. In such a case it is possible, for example, for the following descriptions of the potential supplied to the beam tube to be applied to the lower beam tube portion with the lower second end arranged in the proximity of the objective lens.

According to some embodiments, a computer program product comprises instructions which, when executed by the controller of the electron beam system, cause the electron beam system to perform the method.

Embodiments of the invention are explained in detail below with reference to figures. In detail:

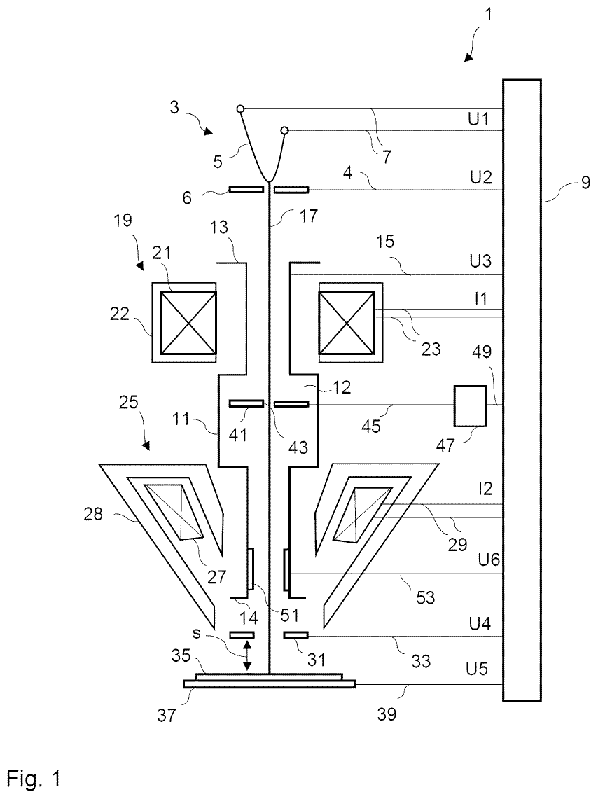

FIG. 1 shows a schematic configuration of an electron beam system according to an embodiment;

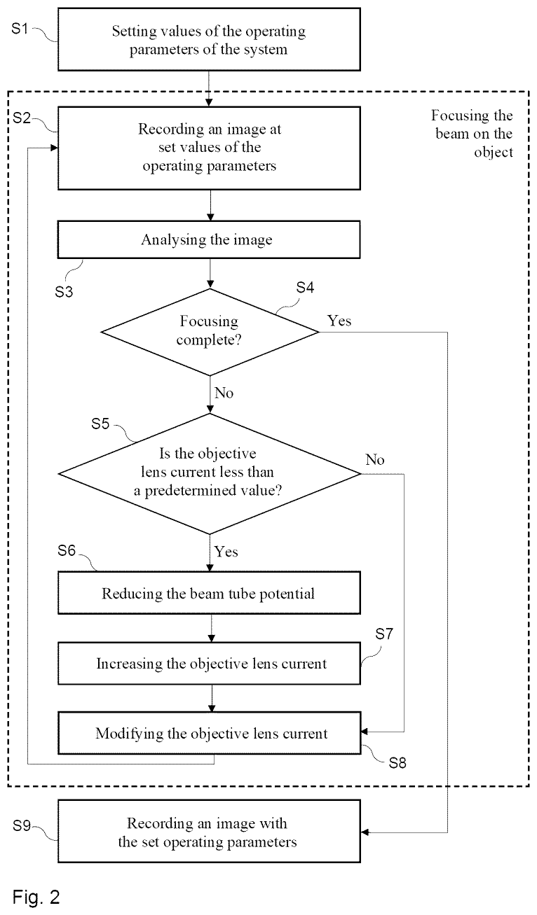

FIG. 2 shows a flowchart showing the method for operating the electron beam system from FIG. 1 according to an embodiment;

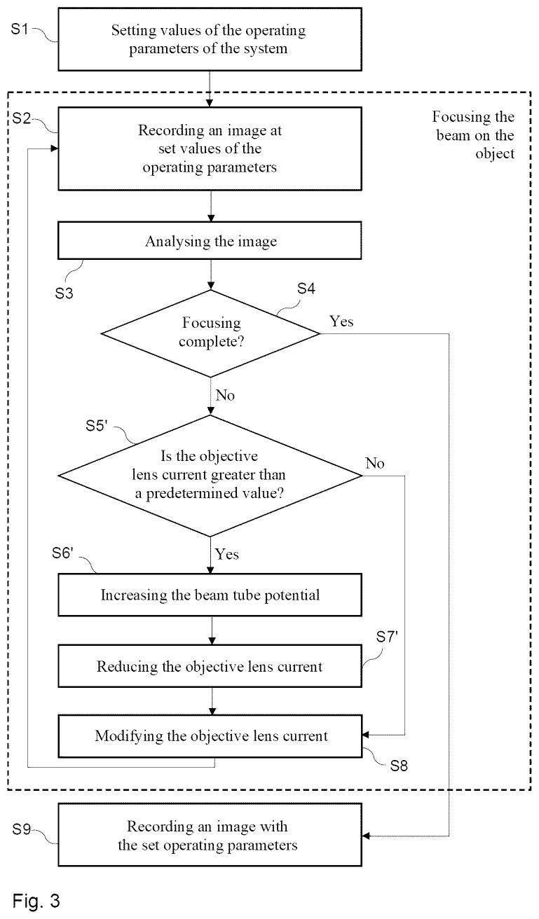

FIG. 3 shows a flowchart showing the method for operating the electron beam system from FIG. 1 according to a further embodiment;

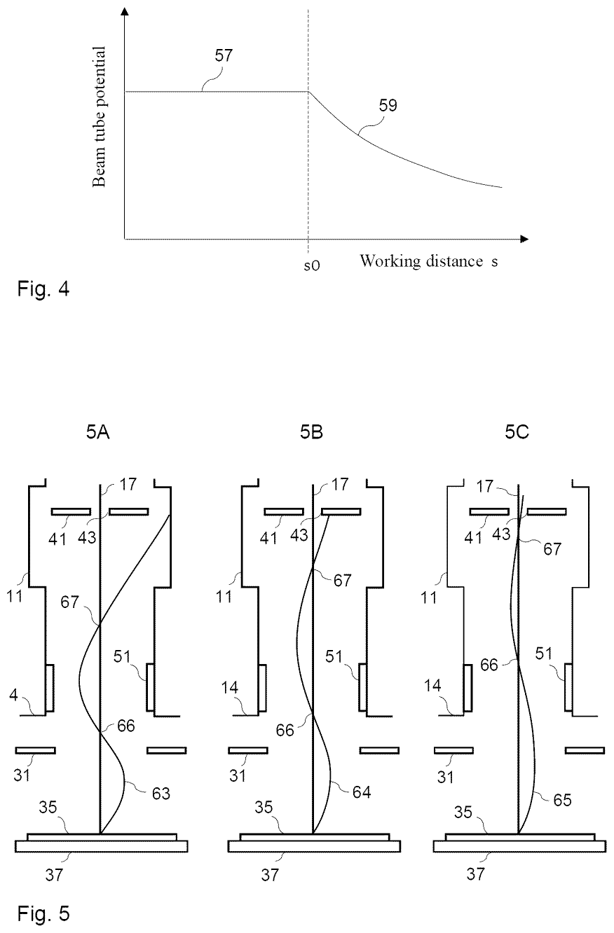

FIG. 4 shows a diagram showing a curve of a voltage applied to the beam tube according to the method shown in FIG. 2;

FIG. 5 shows three schematic illustrations of a trajectory of an electron for different settings of the electron beam system shown in FIG. 1;

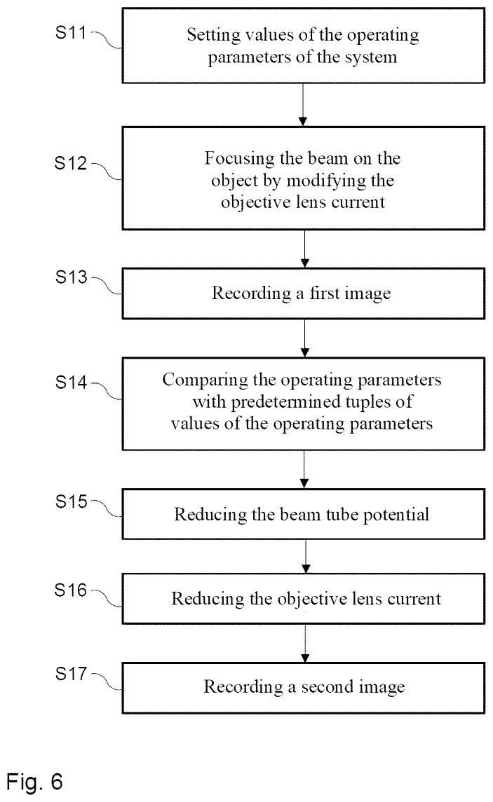

FIG. 6 shows a flowchart showing the method for operating the electron beam system from FIG. 1 according to a further embodiment;

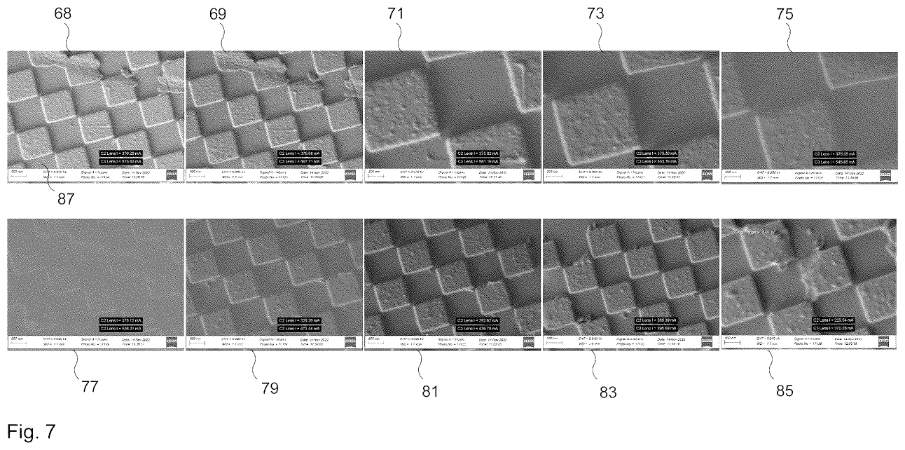

FIG. 7 shows a number of electron-microscopic images recorded using the method shown in FIG. 6 for operating the electron beam system shown in FIG. 1;

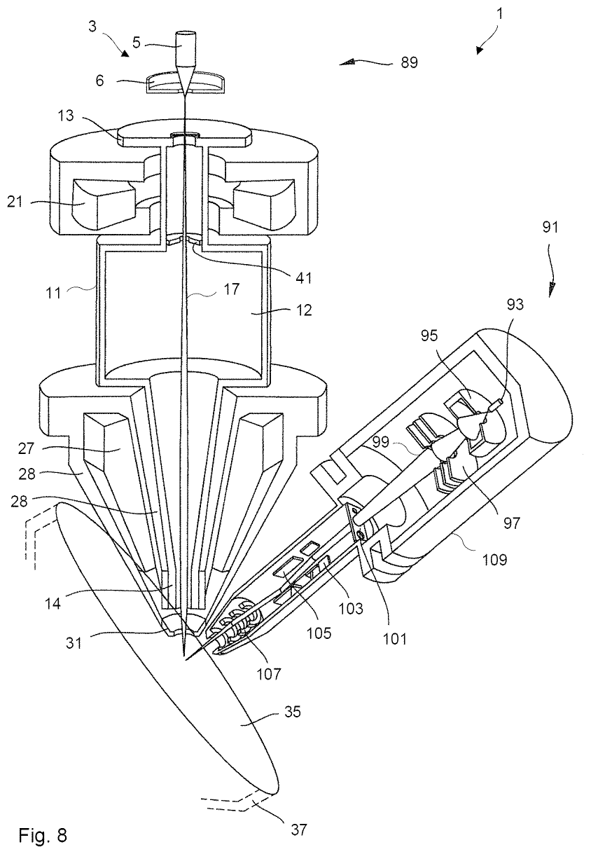

FIG. 8 shows a schematic configuration of an electron beam system according to a further embodiment.

FIG. 1 shows a schematic configuration of an electron beam system 1 according to an embodiment. The electron beam system 1 comprises an electron beam source 3 having an electron emitter 5 and an extraction electrode 6. The electron emitter 5 is connected via connection lines 7 to a supply system 9, which is configured to supply a negative electric potential U1 to the electron emitter 5 via the connection lines 7. Moreover, the extraction electrode 6 is connected via a connection line 4 to the supply system 9, which is also configured to supply a positive electric potential U2 to the extraction electrode 6 via the connection line 4. Electrons are extracted from the electron emitter 5 as a result of the extraction electrode 6 being supplied with an electric potential U2 opposite to the electric potential U1 supplied to the electron emitter, and these extracted electrons consequently move away from the electron beam source 3 along a directed beam 17.

The electron beam system 1 also comprises a beam tube 11 having an interior 12, an upper end 13 and a lower end 14. The beam tube 11 is connected to the supply system 9 via a connection line 15. The supply system 9 is also configured to supply an electric potential U3 to the beam tube 11. When the electric potential U3 is supplied to the beam tube 11, then the upper end 13 of the beam tube 11 acts as an anode which accelerates the electrons in the beam 17 generated by the electron beam source 3 into the beam tube 11. The beam 17 of electrons passes through the beam tube 11. The interior 12 of the beam tube 11 serves to accommodate further components of the electron beam system 1 within the beam tube 11. To this end, the interior 12 is wider than other locations of the beam tube 11, whereby the further components can be arranged in the interior 12 without blocking the beam 17 of electrons.

The beam 17 of electrons passes through a condenser lens 19. The condenser lens 19 is a magnetic lens which deflects the electrons in the beam 17 by generating a magnetic field. To this end, the condenser lens 19 comprises solenoids 21 which are connected to the supply system 9 via connection lines 23. The supply system 9 is also configured to supply an electric current I1 to the solenoids 21 of the condenser lens 19. The condenser lens 19 also comprises a pole shoe 22 which influences the magnetic field created by the current I1 supplied to the solenoids 21 such that this magnetic field suitably enters into the path of the beam 17 of electrons in order to achieve a focusing effect on the beam 17 of electrons.

After the electrons in the beam 17 have passed through any component arranged in the interior 12 of the beam tube 11, the beam 17 passes through the magnetic field of an objective lens 25 which acts within and outside of the beam tube 11. The objective lens 25 is a magnetic lens comprising solenoids 27. The solenoids 27 are connected to the supply system 9 via connection lines 29. The supply system 9 is also configured to supply an electric current I2 to the solenoids 27 via the connection lines 29. A magnetic field which deflects the electrons passing therethrough from their trajectory is generated by the coils 27 when these are supplied with an electric current I2. The objective lens 25 also comprises a pole shoe 28 which influences the magnetic field in such a way that the latter suitably enters into the path of the beam 17 and acts on the electrons in the beam 17 such that a focusing effect is obtained.

The lower end 14 of the beam tube 11 is arranged in the proximity of the objective lens 25. As shown in FIG. 1, the end 14 of the beam tube 11 can be arranged at an opening of the pole shoes 28 of the objective lens 25. As a consequence, the magnetic field of the objective lens 25 acts within and outside of the beam tube 11. In fact, a non-negligible component of the magnetic field of the objective lens 25 acts as far as the object 35 in some embodiments. In particular, this means that the electrostatic field between the beam tube 11 and the object 35 overlaps with the magnetic field of the objective lens 25.

Even though the upper end 13 of the beam tube 11 is shown in the proximity of the condenser lens 19 in FIG. 1, the upper end 13 might also be arranged at any other position along the beam path of the beam 17 for as long as the beam tube 11 has an extent along the beam path of the beam 17 between the upper end 13 and the lower end 14. For example, the upper end 13 might also be arranged in the proximity of the objective lens 25, with the result that the beam tube 11 encloses the beam 17 only at the location where the beam 17 passes through the objective lens 25. Moreover, the beam tube 11 may comprise a plurality of portions which each have two ends. For example, an upper portion may enclose the beam 17 at the location where the beam 17 passes through the condenser lens 19, with the upper portion comprising the upper end 13 of the beam tube 11 and a further end and accordingly not necessarily being in contact with a lower portion of the beam tube 11. Such a lower portion may enclose the beam 17 at the location where the beam 17 passes through the objective lens 25, with this lower portion then comprising the lower end 14 of the beam tube 11 and a further end. In the same way, the beam tube 11 may also comprise a plurality of components, for example a plurality of layered tube elements.

The electron beam system 1 also comprises an electrode 31 which is connected to the supply system 9 via a connection line 33. The supply system 9 can supply the electrode 31 with an electric potential U4 via the connection line 33. If the potential U4 supplied to the electrode 31 differs from the potential U3 supplied to the beam tube 11 then an electrostatic field is formed between the electrode 31 and the lower end 14 of the beam tube 11. More precisely, an electrostatic lens is formed by the electrode 31 together with the lower end 14 of the beam tube 11.

The beam 17 of electrons is incident on an object 35. The object 35 is positioned on an object mount 37 and at a distance s from the electrode 31. The object mount 37 is connected to the supply system 9 via a connection line 39. Thus, the supply system 9 is able to supply an electric potential U5 to the object 35 via the connection line 39 and the object mount 37. An electrostatic field is generated between the object 35 and the lower end 14 of the beam tube 11, or between the object 35 and the electrode 31, as a result of supplying an electric potential U5.

The electrons incident on the object 35 cause electrons to be emitted by the object 35. The electrons emitted by the object 35 comprise what are known as secondary electrons and backscattered electrons. A kinetic energy of the electrons in the beam 17 upon incidence on the object 35 is determined by a difference between the electric potential U1 of the electron emitter 5 and the potential U5 supplied to the object 35. The electrons emitted by the object 35 are accelerated into the beam tube 11 by the electrostatic field between the object 35 and the lower end 14 of the beam tube 11, between the object 35 and the electrode 31 and/or between the electrode 31 and the lower end 14 of the beam tube 11.

The electron beam system 1 also comprises a detector 41 for detecting the electrons emitted by the object 35. The detector 41 is arranged within the beam tube 11 and comprises an opening 43 through which the beam 17 of electrons can pass through the detector 41. The detector 41 is connected to a controller 47 via a connection line 45, via which the controller 47 can receive measured data from the detector 41.

The electron beam system 1 additionally comprises a deflection device 51 which is connected to the supply system 9 via a connection line 53. The supply system 9 can supply the deflection device 51 with a voltage U6 via the connection line 53. An electric field deflecting electrons passing through the deflection device 51 from their trajectory is generated by the deflection device 51 as a result of a voltage U6 being supplied. A given voltage value generates a certain deflection angle for the beam 17 of electrons. The deflection angle also corresponds to a position at which the beam 17 of electrons is incident on the object 35. As a result, the beam 17 of electrons can be scanned over the object by virtue of each position of incidence of the beam 17 of electrons on the object 35 being assigned measured data from the detector 41. This means that an electron-microscopic image can be generated by the electron beam system 1 by virtue of being able to scan a region on the object 35. This means that measured data from the detector 41 are recorded in a sequence of locations at which the beam 17 is directed by the deflection device 51. In this case, the locations for example are a predetermined set of locations in the region of the object 35 to be scanned.

The controller 47 is also connected to the supply system 9 via a connection line 49. As a result of the connection line 49, the controller 47 is able to provide instructions regarding the value of the electric potential U1 supplied to the electron emitter 5 via the connection lines 7, the value of the electric potential U2 supplied to the extraction electrode 6 via the connection line 4, the value of the electric potential U3 supplied to the beam tube 11 via the connection line 15, the value of the electric current I1 supplied to the solenoids 21 of the condenser lens 19 via the connection lines 23, the value of the electric current I2 supplied to the solenoids 27 of the objective lens 25 via the connection lines 29, the value of the voltage U6 supplied to the deflection device 51 via the connection line 53, the value of the electric potential U4 supplied to the electrode 31 via the connection line 33 and the value of the electric potential U5 supplied to the object 35 via the connection line 39 and the object mount 37.

FIG. 2 shows a flowchart showing the method for operating the electron beam system 1 shown in FIG. 1 according to an embodiment. FIG. 2 shows steps S1 to S9, which are performed by the electron beam system 1. In particular, steps S1 to S9 can be instructed by the controller 47.

Values of the operating parameters of the electron beam system 1 are set in step S1. In particular, the controller 47 of the electron beam system 1 can instruct the supply system 9 to supply a first potential U1 at a first value to the electron emitter 5, supply a second potential U3 at a second value to the beam tube 11 and supply a third potential U5 at a third value to the object 35. In this case, the potential U5 supplied to the object 35 is greater than the potential U1 supplied to the electron emitter 5 and the potential U3 supplied to the beam tube 11 is greater than the potential U5 supplied to the object 35. In other words, firstly, the difference between the potential U1 supplied to the electron emitter 5 and the potential U5 supplied to the object 35 is positive. This is done so that the electrons in the beam 17 experience an accelerating force along their path and are in actual fact accordingly able to be incident on the object 35. Secondly, a difference between the potential U3 supplied to the beam tube 11 and the potential U5 supplied to the object 35 is negative so that the electrons in the beam are decelerated between the emergence from the lower end 14 of the beam tube 11 and the incidence on the object 35. Such a deceleration is advantageous since the electrons are incident on the object 35 with a lower kinetic energy in that case and do not damage the object or cause other unwanted effects, for example significant charging of the object 35.

Then, in step S2, the beam 17 is focused on the object 35 by modifying the current I2 of the objective lens 25. Focusing the beam on the object comprises steps S2 to S8.

Initially, in step S2, an electron-microscopic image is recorded by the electron beam system 1 at the current value of the current I2 of the objective lens 25. Then, in step S3, the recorded electron-microscopic image is analysed to the effect of whether the beam 17 of electrons is focused with the current values of the operating parameters. For example, this analysis can be performed by the user of the electron beam system 1 or in software-based fashion. For example, a sharpness of the electron-microscopic image is examined to this end. For example, the sharpness can be determined by virtue of the image being subjected to a Fourier transform and the contribution of high-frequency components being evaluated. Whether or not the focusing has been completed can be determined by this analysis, as depicted in step S4. If the focusing has been completed, then the electron beam system 1 finishes the focusing of the beam 17 and transitions to step S9, in which an electron-microscopic image is recorded with the set operating parameters.

If the focusing has not been completed, then the electron beam system 1 continues with step S5, in which it carries out a check as to whether the current of the objective lens 25 is less than a predetermined value. In this case, the predetermined value may depend on the set value of the potential U3 supplied to the beam tube 11.

If the current I2 of the objective lens 25 is determined in step S5 to be less than the predetermined value, then the potential U3 supplied to the beam tube 11 is reduced in step S6 and the current I2 supplied to the objective lens 25 is increased in step S7. As a consequence, the current I2 supplied to the objective lens 25 can be reduced further without dropping below the predetermined value. For example, the predetermined value is a small value near zero, at which the current of the objective lens 25 could not be reduced further. After increasing the current of the objective lens 25, the electron beam system 1 continues with step S8, in which the objective lens current I2 is modified on the basis of a result of the analysis performed in step S3. In this case, the modification performed in step S8 corresponds to a modification of the current I2 supplied to the objective lens 25 which would also be performed within the scope of a conventional method for focusing the beam 17 of electrons on the object 35.

If the current I2 of the objective lens 25 is determined in step S5 to not be less than the predetermined value, then the electron beam system 1 skips steps S6 to S7 and advances directly to step S8. As a consequence, the potential U3 supplied to the beam tube 11 is not modified when the current I2 supplied to the objective lens 25 is sufficiently large.

It should be observed that FIG. 2 shows a case in which steps S2 to S8 are an iterative step of focusing the beam 17 on the object 35. In an alternative, however, steps S5 to S7 could also be performed in every second iterative step, every third iterative step, etc. of focusing the beam 17 on the object 35. Moreover, steps S5 to S7 could alternatively also be performed after step S8. If the current I2 supplied to the objective lens 25 is determined as not being smaller than the predetermined value in step S5 in such a case, then the electron beam system 1 returns directly to step S2. In other words, step S8 in such an embodiment is located between steps S4 and S5 shown in FIG. 2 and, after execution of step S7 or after determination that the current supplied to the objective lens 25 is not less than the predetermined value in step S5, the electron beam system 1 returns to step S2.

As a result of the method described above with reference to FIG. 2, it is possible to further reduce the current supplied to the objective lens 25, even if the current becomes virtually zero. For example, if the distance s, at which the object 35 is arranged in relation to the electron beam system 1, is large, then the situation may arise where the beam 17 cannot be focused on the object 35 in the case of a constant potential U3 supplied to the beam tube 11 because the electrostatic field between the electrode 31 and the lower end 14 of the beam tube 11 and/or between the object 35 and the lower end 14 of the beam tube 11 has a focusing effect with regards to the beam 17 of electrons. Therefore, the beam 17 of electrons converges even if no current is supplied to the objective lens 25. However, if the voltage supplied to the beam tube 11 is reduced, then there is also a reduction in the focusing effect of the electrostatic field. As a result, the same focusing effect can be obtained with a smaller potential U3 supplied to the beam tube 11 and a higher current supplied to the objective lens 25.

It should be observed that in the description above a current is supplied to the objective lens 25 in order to obtain a focusing effect. However, an electric current can be supplied to the condenser lens 19 in an alternative or in addition.

A further embodiment is described below with reference to FIG. 3. FIG. 3 shows a flowchart showing the method for operating the electron beam system 1 from FIG. 1 according to a further embodiment. In this case, the method shown in FIG. 3 is reversed to the method shown in FIG. 2 and differs in terms of steps S5′, S6′ and S7′ in particular. That is to say, a distance of a focal point of the beam 17 from the electron beam system 1 is reduced in the method shown in FIG. 3 while this distance is increased in the method shown in FIG. 2.

A further embodiment is described below with reference to FIG. 3. FIG. 3 shows a flowchart showing the method for operating the electron beam system 1 from FIG. 1 according to a further embodiment. FIG. 3 shows steps S6 to S10, which are to be carried out by the electron beam system 1. The method shown in FIG. 3 is the reversed method to the method shown in FIG. 2. That is to say, a distance of a focal point of the beam 17 from the electron beam system 1 is reduced in the method shown in FIG. 3 while this distance is increased in the method shown in FIG. 2.

If the current supplied to the solenoids 27 of the objective lens 25 is determined to be greater than the predetermined value in step S5′ shown in FIG. 3, then the electron beam system 1 continues with steps S6′ and S7′. In step S6′, the potential U3 supplied to the beam tube 11 is increased and, in step S7′, the current I2 supplied to the objective lens 25 is reduced. After step S7′ has been carried out, the electron beam system 1 returns to step S2. The corresponding descriptions regarding alternative embodiments in respect of FIG. 2 also apply accordingly to the method shown in FIG. 3 with steps S5′ to S7′.

Below, the method shown in FIG. 2 is explained in detail in relation to FIG. 4. FIG. 4 shows a diagram showing a curve of the voltage applied to the beam tube according to the method shown in FIG. 2.

On its abscissa, the diagram in FIG. 4 shows the working distance s, shown in FIG. 1, between the object 35 and the electrode 31. The working distance s can also be referred to as the distance between the object 35 and the electron beam system 1. Moreover, on the ordinate, the diagram in FIG. 4 shows the potential U3 supplied to the beam tube 11. FIG. 4 also shows a graph with sections 57 and 59. The constant section 57 is a region in which conventional methods can be applied without the function of the electron beam system 1 being impaired. The constant section 57 reaches up to a working distance s0. If the object 35 is arranged at a distance greater than the distance s0, then conventional methods for operating an electron beam system cannot focus the beam 17 on the object 35.

The curved section 59 shows the potential U3 supplied to the beam tube 11 after performing the method shown in FIG. 2. In other words, the curved section 59 shows the potential U3 supplied to the beam tube 11 and used to operate the electron beam system 1 for further use. It is evident here that the potential U3 set after the method has been performed and supplied to the beam tube 11 is no longer constant and reduces for greater working distances s. As a result, the electron beam system 1 can be operated without loss of functionality.

A further embodiment of the method for operating the electron beam system 1 is explained on the basis of the schematic illustrations shown in FIG. 5. FIG. 5 shows three schematic illustrations 5A, 5B and 5C of a trajectory of an electron for different settings of the electron beam system 1 shown in FIG. 1. In detail, the potentials U3 supplied to the beam tube 11 are different in the three schematic illustrations 5A, 5B and 5C. In this case, the potential U3 supplied to the beam tube 11 is lowest in the case of the schematic illustration 5A and highest in the case of the schematic illustration 5C.

The schematic illustrations 5A, 5B and 5C show the components of the electron beam system 1 which were already described in relation to FIG. 1. In this case, a detector 41 with an opening 43 through which the beam 17 of electrons passes is arranged in the beam tube 11. Moreover, the beam tube 11 comprises a lower end 14 which generates an electrostatic field together with the electrode 31 and the object 35 mounted on the object mount 37. The beam 17 of electrons is not deflected by the deflection device 51 in the case of the schematic illustrations 5A, 5B and 5C.

A case in which a high potential U3 is applied to the beam tube 11 is described below with reference to the schematic illustration 5C. The electrons in the beam 17 incident on the object 35 cause the object 35 to emit an electron 65. The electron 65 is emitted in a direction at which it would not enter the beam tube without the influence by the electrostatic field generated between the beam tube 11 and the object 35. Since the potential U3 applied to the beam tube 11 is high, the electron 65 experiences significant acceleration in the direction of the beam tube 11 and is moreover subjected to the focusing effect of the electrostatic field generated between the beam tube 11 and the object 35, and to the magnetic field generated by the objective lens 25. As a result, the electron 65 crosses the beam 17 at a first crossing point 66. It should be observed that this does not mean that the electron 65 actually passes through the beam 17. Even if the electron 65 comes into the proximity of the beam 17 and does not travel past the beam 17 in a dimension perpendicular to the plane of the drawing, the electron 65 will not strike the electrons in the beam 17 on account of the electrical repulsion between the electron 65 and the beam.

The electron 65 subsequently crosses the beam 17 at a second crossing point 67. The electron 65 cannot strike the beam 17 at this crossing point 67 either. On account of the high potential U3 supplied to the beam tube 11, the electron 65 is accelerated significantly along its trajectory through the beam tube 11 and passes through the latter at a high speed or with a high energy. Further interactions such as the focusing effect of the electrostatic lens accordingly act only briefly on the electron 65, whereby the trajectory of the electron 65 runs close to the beam 17. It is for this reason that the electron 65 passes through the opening 43 in the detector 41 and cannot be detected by the detector 41.

The schematic illustration 5B shows a case in which the beam tube 11 is supplied a potential U3 which is lower than the potential U3 supplied to the beam tube 11 in the case of the schematic illustration 5C. The electrons in the beam 17 incident on the object 35 cause the object 35 to emit an electron 64. The electron 64 is emitted in the same direction and with the same energy as the electron 65. Since the potential U3 supplied to the beam tube 11 in the schematic illustration 5B is lower than that in the schematic illustration 5C, the electron 64 is accelerated into the beam tube 11 less strongly than the electron 65. Accordingly, the electron 64 has a longer exposure to the respective interactions, for example the focusing effect of the electrostatic field between the lower end 14 of the beam tube 11, and also the magnetic field of the objective lens 25. Moreover, the magnetic field of the objective lens 25 is stronger in illustration 5B than in illustration 5C since a greater current I2 is supplied to the objective lens 25 in order to maintain the focusing effect of the electron beam system 1. For these reasons, the electron 64 crosses the beam 17 at a crossing point 66 which is significantly closer to the object 35 than the first crossing point 66 of the electron 65. The electron 64 subsequently crosses the beam 17 at a second crossing point 67. The second crossing point 67 of the electron 64 is also closer to the object 35 than the second crossing point 67 of the electron 65. In other words, the electron 64 passes along a significantly more curved trajectory than the electron 65. Accordingly, the electron 64 is incident on the detector 41 and can be detected by the latter.

The schematic illustration 5A shows a case in which the beam tube 11 is supplied a potential U3 which is lower than the potential U3 supplied to the beam tube 11 in the cases of the schematic illustrations 5B and 5C. The electrons in the beam 17 incident on the object 35 cause the object 35 to emit an electron 63. In this case, the electron 63 is emitted from the object 35 in the same direction and with the same energy as the electrons 64 and 65. Since the potential U3 supplied to the beam tube 11 is smaller than the potential U3 supplied to the beam tube 11 in the cases of the schematic illustrations 5B and 5C, the electron 63 is accelerated into the beam tube 11 to a significantly lesser extent, whereby the electron 63 passes through the beam tube 11 at a lower speed. Moreover, the magnetic field of the objective lens 25 is stronger in illustration 5A than in illustrations 5B and 5C since a greater current I2 is supplied to the objective lens 25 in order to maintain the focusing effect of the electron beam system 1. For these reasons, the electron 63 is influenced more than the electrons 64 and 65 in schematic illustrations 5B and 5C. Of the cases shown in the schematic illustrations 5A, 5B and 5C, the first crossing point 66 at which the electron 63 crosses the beam 17 is the closest to the object 35. The same also applies to the second crossing point 67 where the electron 63 crosses the beam 17 a second time. In other words, the trajectory of the electron 63 is more curved than the trajectories of the electrons 64 and 65. As a consequence, the electron 63 strikes the beam tube 11 rather than the detector 41, whereby the electron 63 cannot be detected by the detector 41.

It should be observed that, to facilitate understanding, the schematic illustrations 5A, 5B and 5C in FIG. 5 show the trajectory of only one respective electron emitted by the object 35. However, in practice the object 35 will emit a plurality of electrons in different directions and with different energies. FIG. 5 is intended to be understood in the sense that the probability of an electron striking the detector 41 is higher for the schematic illustration 5B than for the cases in schematic illustrations 5A and 5C. Accordingly, it is self-evident that a switchover from the case shown in schematic illustration 5C to the case shown in schematic illustration 5B will increase the signal detected by the detector 41. This can improve a quality of an electron-microscopic image. It should also be observed that the probability of incidence is reduced if the potential U3 supplied to the beam tube 11 is too low, for example as depicted in schematic illustration 5A in FIG. 5.

Since the trajectories and interactions of the electrons 63, 64 and 65 depend on a plurality of settings and the configuration of the electron beam system 1, the probabilities of electron incidence elucidated in FIG. 5 are also dependent on the settings and the configuration of the electron beam system 1. For example, a configuration of the objective lens 25 may cause the probability of incidence of the electrons emitted by the object 35 to already be reduced at very much higher voltage values. The probabilities of incidence of the electrons emitted by the object 35 can be determined for specific settings and configurations of the electron beam system 1 by simulating the trajectories of the electrons and by virtue of determining the number of electrons incident on the detector 41.

FIG. 6 shows a flowchart showing the method for operating the electron beam system 1 shown in FIG. 1 according to this embodiment. In this case, FIG. 6 shows steps S11 to S16. Initially, values of the operating parameters of the electron beam system 1 are set in step S11. In particular, the controller 47 instructs the supply system 9 to supply a first potential U1 at a first value to the electron emitter 5, a second potential U3 at a second value to the beam tube 11 and a third potential U5 at a third value to the object 35.

Then, in step S12, the beam 17 is focused on the object 35 by modifying the current of the objective lens 25. In contrast to the methods described above in relation to FIGS. 2 and 3, the focusing of the beam 17 on the object 35 is completely finished in this embodiment before there is a transition to the next step. As soon as the electron beam system 1 has reached a focused state, the electron beam system 1 continues with step S13. It should be observed that the focusing may also comprise iterative steps here; in a manner similar to steps S2, S3, S4 and S7, these may include recording an electron-microscopic image, analysing the recorded electron-microscopic image and modifying the current supplied to the objective lens 25 on the basis of the analysis of the image.

Subsequently, a first electron-microscopic image is recorded in step S13. For example, this image corresponds to an image on the basis of which a user of the electron beam system 1 decides that it is desirable to switch over to an operating mode which increases the signal detected by the detector 41 rather than the resolution of the electron beam system 1. In step S14, the operating parameters are then compared with predetermined tuples of values of the operating parameters. The tuples contain values which arise from a simulation in which the number of electrons incident on the detector 41 is determined for different operating parameter settings. For example, such a simulation can be realized by virtue of simulating trajectories of electrons with different emission energies and directions, in a manner corresponding to the example shown in FIG. 5. The values determined by the simulation can then be stored, in a memory of the electron beam system 1 or in a cloud, in the form of tuples which can be accessed by the electron beam system 1. Alternatively, the tuples may contain values determined by experiment. For example, an experimental determination can be performed by collecting and processing feedback from a user of the electron beam system. On the basis of the predetermined tuples, it is possible to determine the values of the potential U3 supplied to the beam tube 11 and of the current supplied to the objective lens 25 that are to be set. For example, this can be implemented by virtue of an entry of tuples being read, in which the current values of the operating parameters with the exception of the potential U3 supplied to the beam tube 11 and the current supplied to the objective lens 25 correspond to the values of the tuples.

Then, in step S15, the potential U3 supplied to the beam tube 11 is reduced and, in step S16, the current supplied to the objective lens 25 is reduced in accordance with the values determined in step S14. In this case, the current supplied to the objective lens 25 in step S16 is reduced in such a way that the focusing on the object 35 is maintained. That is to say, the beam 17 of electrons is focused on the object 35 even after steps S15 and S16.

The method continues with step S17 after the new values of the potential U3 of the beam tube 11 and of the current of the objective lens 25 have been set. A second electron-microscopic image is recorded in step S17 using the electron beam system 1 at the set values.

For example, the method can be implemented as a switchover between two operating modes, which can be performed by a user of the electron beam system 1. In such a case, the electron beam system 1 may comprise a first operating mode, in which electron-microscopic images are recorded at a first, unchanging value for the potential U3 supplied to the beam tube 11, and a second operating mode, in which electron-microscopic images are recorded at a second value of the potential U3 supplied to the beam tube 11, the second value being optimized in relation to the electrons incident on the detector 41. Accordingly, the method can switch over from the first operating mode to the second operating mode as a result of steps S11 to S17.

According to further embodiments, the second operating mode can alternatively be chosen such that steps S14 to S16 are performed in order to reduce a convergence angle of the beam 17 of electrons focused on the object 35 in relation to the convergence angle in the first operating mode. The convergence angle influences the theoretically possible resolution of the electron-microscopic image and a depth of field of the electron-microscopic image. In this case, the depth of field is a measure for the sharpness of the electron-microscopic image at different levels of the object 35 in the case of an unchanging focus of the beam 17 of electrons. A smaller convergence angle reduces the theoretically possible resolution but increases the depth of field. This may be advantageous if a large region of the sample should be recorded since the sharpness of the electron-microscopic image at the sides, where there is a large deflection by the deflection device 51, is similar to the sharpness of the electron-microscopic image in the centre, wherein the deflection by the deflection device 51 is small. In such a case, the theoretically possible resolution is less relevant since a large region of the object 35 is recorded with a lower density of data points in order to reduce a recording time for the large region of the object 35. For example, a higher depth of field is also advantageous if the object 35 is very uneven and accordingly elevated regions of the object 35 should be recorded at a similar resolution to depressed regions of the object 35.

The method may additionally comprise a switchover from the second operating mode to the first operating mode. In such a case, the electron beam system 1 increases the potential U3 supplied to the beam tube 11 and the current I2 supplied to the objective lens 25 in the opposite sense to the reduction in the potential U3 supplied to the beam tube 11 and the current I2 supplied to the objective lens 25 of steps S15 and S16 shown in FIG. 6.

FIG. 7 shows a number of electron-microscopic images 68, 69, 71, 73, 75, 77, 79, 81, 83 and 85 recorded using the method shown in FIG. 6 for operating the electron beam system 1 shown in FIG. 1. In this case, the electron-microscopic images 68, 69, 71, 73, 75, 77, 79, 81, 83 and 85 were recorded using a Zeiss GeminiSEM 560. The images 68, 69, 71, 73, 75, 77, 79, 81, 83 and 85 show an electron-microscopic recording of an object which exhibits structures 87 arranged in a chequerboard pattern.

Image 68 was recorded at a potential U3 of 8000 volts supplied to the beam tube 11 and at a voltage of 90 volts between the electron emitter 5 and the object 35. Image 69 was recorded at a potential U3 of 8000 volts supplied to the beam tube 11 and at a voltage of 80 volts between the electron emitter 5 and the object 35. Image 71 was recorded at a potential U3 of 8000 volts supplied to the beam tube 11 and at a voltage of 70 volts between the electron emitter 5 and the object 35. Image 73 was recorded at a potential U3 of 8000 volts supplied to the beam tube 11 and at a voltage of 60 volts between the electron emitter 5 and the object 35. Image 75 was recorded at a potential U3 of 8000 volts supplied to the beam tube 11 and at a voltage of 50 volts between the electron emitter 5 and the object 35.

Image 77 was recorded at a potential U3 of 8000 volts supplied to the beam tube 11 and at a voltage of 40 volts between the electron emitter 5 and the object 35. Image 79 was recorded at a potential U3 of 6000 volts supplied to the beam tube 11 and at a voltage of 40 volts between the electron emitter 5 and the object 35. Image 81 was recorded at a potential U3 of 5000 volts supplied to the beam tube 11 and at a voltage of 40 volts between the electron emitter 5 and the object 35. Image 83 was recorded at a potential U3 of 4000 volts supplied to the beam tube 11 and at a voltage of 40 volts between the electron emitter 5 and the object 35. Image 85 was recorded at a potential U3 of 3400 volts supplied to the beam tube 11 and at a voltage of 40 volts between the electron emitter 5 and the object 35.

It is evident that the method described above with reference to FIG. 6 is advantageous for low voltages between the electron beam emitter 5 and the object 35 in particular. Images 68 to 77 show that an incremental reduction in the voltage between the electron beam emitter 5 and the object 35 is accompanied by a reduction in the signal generated by the detector 41 and in particular by a reduction in a contrast between the structure elements 87. For example, it is virtually impossible to identify the structure elements 87 in the image 77. However, if the potential U3 supplied to the beam tube 11 is reduced while the focus of the beam 17 of electrons remains unchanged, as shown incrementally in images 79 to 85, then a quality of the recorded electron-microscopic images increases, especially in relation to the contrast of the structure elements 87. In enlarged image 85, in particular, fine details on the object 35 can be identified.

FIG. 8 shows a schematic configuration of an electron beam system 1 according to a further embodiment. In this case, the electron beam system 1 comprises an electron beam column 89 having the components already described above, and an ion beam column 91. The ion beam column 91 comprises an ion beam source 93 comprising a metal reservoir and a tip on which a drop of molten metal runs down from the metal reservoir. For example, the metal can be gallium which has a low melting point. An extraction electrode 95 releases ions from the molten material. To this end, the extraction electrode 95 is brought to an electric potential which is lower than a potential of the ion beam source 93. The released ions pass through the extraction electrode 95 and form a beam 99 of ions.

The beam 99 of ions then passes through a condenser lens 97. The condenser lens 97 is an electrostatic lens which for example can be a single lens, as shown in FIG. 8. The condenser lens 97 shown in FIG. 8 consists of three electrodes between which an electrostatic field is generated in each case, the field entering the path of the beam 99. The ions of the beam 99 pass through the electrostatic field of the condenser lens 97 and are consequently collimated.

The ion beam column 91 also comprises a variable aperture 101 in the path of the beam 99. The variable aperture 101 allows an intensity of the beam 99 incident on the object 35 to be adjusted since the variable aperture 101 is in a plane optically conjugate to the ion beam source 93. The beam 99 can be deflected relative to the object 35 in two dimensions by deflection electrodes 103, 105. As a result, the beam 99 can be directed at a specific processing position on the object 35.

The ion beam column 91 additionally comprises an objective lens 107. The objective lens 107 is an electrostatic lens which can be a single lens, for example. The objective lens shown in FIG. 8 comprises three ring electrodes between which an electric field can be generated, the field entering the path of the beam 99. As a result, the ions of the beam 99 are deflected, whereby the objective lens 107 has a focusing effect. As a result of the influence of the incident ions, the beam 99 focused on the object 35 at a processing position can then be used for cutting, material deposition, or the like.

The ion beam column 91 also comprises a housing 109 which accommodates the components of the ion beam column 91 therein. As a result of combining the electron beam column 89 with the ion beam column 91, the electron beam system 1 can be operated in various modes of operation. For example, the electron beam source 3 can be switched off, i.e. no voltage is applied to the electron emitter 5, and electrons emitted by the object 35, which are emitted from the object 35 by the incident beam 99 of ions, can be detected by the detector 41 of the electron beam column 89. In another exemplary operating mode, the electron beam column 89 and the ion beam column 91 are both operated as described above.

After the beam 99 of ions emerges from the housing 109, the ions are exposed to the electrostatic field which is prevalent between the electron beam column 89 and the object 35. Hence, the ions in the beam 99 are influenced in undesirable fashion. To circumvent these circumstances, conventional methods do not supply voltage to the beam tube 11 in the case of a combination with an ion beam column 91. However, this reduces the number of electrons captured as these are not accelerated into the beam tube 11.

In the above-described method, the second operating mode can for example alternatively be a mode in which the voltage supplied to the beam tube 11 is as low as possible, whereby the beam 99 of ions from the ion beam column 91 is influenced as little as possible by the electrostatic field between the object 35 and the electron beam column 89, but the electrons emitted by the object 35 are nevertheless accelerated into the beam tube 11 to the desired extent. In this operating mode, too, it may be advantageous for the method if the values to be set are predetermined. For example, values for the current supplied to the objective lens 25 and for the potential U3 supplied to the beam tube 11 can be determined by simulation for such an operating mode and can be stored in a memory or a cloud, to which the electron beam system 1 has access.

What is claimed is:

1. A method of operating an electron beam system, the electron beam system comprising: an electron beam source configured to generate a beam of electrons; a beam tube which comprises first and second ends, the beam tube configured so that the beam of electrons enters the beam tube at the first end and emerges from the beam tube at the second end; focusing magnetic lens through which the electron beam passes; and a supply system configured to supply a first potential to an electron emitter of the electron beam source, supply a second potential to the beam tube, supply a third potential to an object and supply a current to the magnetic lens, the method comprising:
setting the first potential to a first value, the second potential to a second value and the third potential to a third value so that the third potential is greater than the first potential and the second potential is greater than the third potential;
focusing the beam on the object by modifying the current; and
when the current meets a predetermined criterion during focusing:
setting the second potential to a fourth value which is less than the second value; and
increasing the current and then continuing to focus the beam on the object by modifying the current, or continuing to focus the beam on the object by modifying the second potential.

2. The method of claim 1, wherein the predetermined criterion is met when the current drops below a predetermined value or when the current does not drop below the predetermined value.

3. The method of claim 1, further comprising influencing electrons between the second end of the beam tube and the object with: i) an electric field generated by a difference between the second potential and the third potential; ii) a field generated by the magnetic lens.

4. The method of claim 1, wherein the predetermined criterion depends on the second value.

5. The method of claim 1, wherein focusing the beam on the object comprises finding a value for the current so that a spot illuminated by the beam on the object is as small as possible.

6. The method of claim 1, wherein focusing the beam on the object comprises detecting electrons generated by the beam of electrons, determining a change in a value of the current based on the detected electrons, and setting the value for the current in accordance with the determined change.

7. The method of claim 1, further comprising recording an electron-microscopic image at the set values for the first, second and third potentials and for the current.

8. The method of claim 7, wherein focusing the beam on the object comprises finding a value for the current so that the recorded electron-microscopic image is as sharp as possible.

9. One or more machine-readable hardware storage devices comprising instructions that are executable by one or more processing devices to perform operations comprising the method of claim 1.

10. A system comprising:
one or more processing devices; and
one or more machine-readable hardware storage devices comprising instructions that are executable by the one or more processing devices to perform operations comprising the method of claim 1.

11. A method of operating an electron beam system, the electron beam system comprising: an electron beam source configured to generate a beam of electrons; a beam tube which comprises a first end and a second end and is configured such that the beam of electrons enters the beam tube at the first end and emerges from the beam tube at the second end; a focusing magnetic lens through which the electron beam passes; and a supply system configured to supply a first potential to an electron emitter of the electron beam source, supply a second potential to the beam tube, supply a third potential to an object and supply a current to the magnetic lens, the method comprising:
setting the first potential to a first value, the second potential to a second value and the third potential to a third value so that the third potential is greater than the first potential and the second potential is greater than the third potential;
focusing the beam on the object by modifying the current; and
when the current meets a predetermined criterion during the focusing:
setting the second potential to a fourth value which is greater than the second value; and
reducing the current and then continuing to focus the beam on the object by modifying the current, or continuing to focus the beam on the object by modifying the second potential.

12. The method of claim 11, wherein the predetermined criterion is met when the current exceeds a predetermined value, and/or when the current does not exceed the predetermined value.

13. A method of operating an electron beam system, the electron beam system comprising: an electron beam source configured to generate a beam of electrons; a beam tube which comprises a first end and a second end and is configured such that the beam of electrons enters the beam tube at the first end and emerges from the beam tube at the second end; a focusing magnetic lens through which the electron beam passes; and a supply system configured to supply a first potential to an electron emitter of the electron beam source, supply a second potential to the beam tube, supply a third potential to an object and supply a current to the magnetic lens, the method comprising:
setting the first potential to a first value, the second potential to a second value and the third potential to a third value so that the third potential is greater than the first potential and the second potential is greater than the third potential;
focusing the beam on the object by modifying the current to a fourth value and recording a first electron-microscopic image at the first value of the first potential, the second value of the second potential, the third value of the third potential and the fourth value of the current;
setting the second potential to a fifth value which is less than the second value, and setting the current to a sixth value which is less than the fourth value;
recording a second electron-microscopic image at the first value of the first potential, the fifth value of the second potential, the third value of the third potential and the sixth value of the current.

14. The method of claim 13, further comprising determining the fifth and sixth values based on the first value, the second value, the third value and the fourth value so that the beam is substantially focused on the object at the first value of the first potential, the fifth value of the second potential, the third value of the third potential and the sixth value of the current.

15. The method of claim 14, further comprising using a predetermined data record when determining the fifth value and the sixth value, wherein the predetermined data record comprises a multiplicity of tuples of values of the first potential, the second potential, the third potential, the current and a distance of the electron beam system at which the focus of the beam arises.

16. The method of claim 14, wherein:
the electron beam system further comprises a detector next to the beam of electrons within the beam tube; and
the determination is implemented so that an intensity of electrons incident on the detector or a ratio of a current of the beam of electrons focused on the object to the intensity of electrons incident on the detector is greater than during the recording of the first electron-microscopic image.

17. The method of claim 16, wherein the second value is chosen so that a resolution of the first image is maximal.

18. The method of claim 13, wherein the determination is implemented in such a way that a convergence angle of the beam of electrons focused on the object is smaller than during the recording of the first electron-microscopic image.

19. The method of claim 13, wherein:
the electron beam system further comprises an ion beam column configured to direct an ion beam at the object; and
the method further comprises operating the ion beam column while the second electron-microscopic image is recorded.

20. The method of claim 13, wherein the operation of the ion beam column comprises a removal of material from the object using the ion beam or a severing of material from the object by the ion beam.
